(19) United States
(12) Patent Application Publication
(10) Pub. No.: US 2012/0235218 A1
(43) Pub. Date: Sep. 20, 2012

(54) SEMICONDUCTOR DEVICE AND METHOD OF MANUFACTURING THE SAME

(76) Inventors: Hiroyuki KUTSUKAKE, Yokohama-shi (JP); Noboru Shibata, Kawasaki-shi (JP); Kazushige Kanda, Kawasaki-shi (JP); Masayuki Ichige, Yokohama-shi (JP)

(21) Appl. No.: 13/235,397

(22) Filed: Sep. 18, 2011

(30) Foreign Application Priority Data
Mar. 17, 2011 (JP) 2011-059821

(51) Int. Cl. H01L 27/115; H01L 21/8239

(52) U.S. Cl. 257/314; 438/200; 257/E27.103; 257/E21.645

(57) ABSTRACT

According to one embodiment, a device includes a semiconductor substrate, a first region including a first well which is formed in substrate, a second well which is formed in substrate and on first well, and a memory cell which is formed on second well, and a second region including a third well which is formed in substrate, and a first transistor which is formed on third well. The device includes a third region including a second transistor which is formed on semiconductor substrate, and a fourth region including a fourth well which is formed in semiconductor substrate, a fifth well which is formed in substrate and on fourth well, and a third transistor which is formed on fifth well. Bottoms of first well and fourth well are lower than a bottom of third well, and bottom of third well is lower than bottoms of second well and fifth well.

### CROSS-REFERENCE TO RELATED APPLICATIONS

This application is based upon and claims the benefit of priority from prior Japanese Patent Application No. 2011-059821, filed Mar. 17, 2011, the entire contents of which are incorporated herein by reference.

### FIELD

Embodiments described herein relate generally to a semiconductor device and a method of manufacturing the same.

### BACKGROUND

In recent years, with an increase in capacity of memories, there has been developed a multi-value memory which stores 2 bits or more in one cell. For example, in order to store 2 bits in one cell, it is necessary to set four threshold distributions in a range which does not exceed Vread. Thus, compared to the case where 1 bit (two threshold distributions), are stored in one cell, it is necessary to control narrower threshold distributions. Moreover, in order to store 3 bits or 4 bits in one cell, 8 or 16 threshold distributions have to be set. It is thus necessary to greatly narrow the distribution width of each threshold voltage. In this manner, in order to narrow the distribution width of the threshold voltage, it is necessary to exactly repeat program and verify, leading to the write speed lowers.

To keep the write speed, there is thought a method in which a plurality of threshold voltage distributions are set on a negative voltage side which is lower than 0V. According to this method, compared to the case in which threshold voltage distributions are provided on only the positive voltage side, the threshold voltage distributions of data can be broadened. Thus, the number of times of program and verify can be decreased, and the write speed can be increased.

In addition, in the case of supplying a negative voltage to the gate of a selected cell, it is necessary to set a word line at a negative potential. And a substrate, on which a high-voltage N-channel MOS transistor HVN-Tr that constitutes a row decoder is formed, has to be also set at a negative potential. By forming, in an N well, a P well in which a low-voltage N-channel MOS transistor LVN-Tr of a data memory circuit is formed, the flow of a forward current is prevented when the substrate is set at a negative potential. Thus, the electric current consumption can be reduced.

However, no consideration has been given to a concrete structure of a well or a concrete method of forming a well of a semiconductor device which can obtain such an advantageous effect.

### BRIEF DESCRIPTION OF THE DRAWINGS

FIG. 1 is a block diagram showing a basic structure of a semiconductor device according to an embodiment.

FIG. 2 shows structures of a memory cell array and a bit line control circuit shown in FIG. 1.

FIG. 3A is a cross-sectional view showing an example of a basic structure of a semiconductor device according to a first embodiment.

FIG. 3B is a cross-sectional view showing another example of the basic structure of the semiconductor device according to the first embodiment.

FIG. 3C is a cross-sectional view showing still another example of the basic structure of the semiconductor device according to the first embodiment.

FIG. 4 is a circuit diagram showing an example of a data memory circuit 9 shown in FIG. 2.

FIG. 5 shows a transfer gate which constitutes a part of a row decoder.

FIG. 6 is a view for explaining a read operation.

FIG. 7 is a cross-sectional view which schematically illustrates a part of a basic manufacturing method of the semiconductor device according to the first embodiment.

FIG. 8 is a cross-sectional view which schematically illustrates a part of the basic manufacturing method of the semiconductor device according to the first embodiment.

FIG. 9 is a cross-sectional view which schematically illustrates a part of the basic manufacturing method of the semiconductor device according to the first embodiment.

FIG. 10A is a cross-sectional view showing a basic structure of a semiconductor device according to a second embodiment.

FIG. 10B is a cross-sectional view showing the basic structure of the semiconductor device according to the second embodiment.

FIG. 11 is a cross-sectional view which schematically illustrates a part of a basic manufacturing method of the semiconductor device according to the second embodiment.

FIG. 12 is a cross-sectional view which schematically illustrates a part of the basic manufacturing method of the semiconductor device according to the second embodiment.

FIG. 13 is a cross-sectional view which schematically illustrates a part of the basic manufacturing method of the semiconductor device according to the second embodiment.

FIG. 14A is a cross-sectional view showing a basic structure of a semiconductor device according to a third embodiment.

FIG. 14B is a cross-sectional view showing the basic structure of the semiconductor device according to the third embodiment.

FIG. 15 is a cross-sectional view which schematically illustrates a part of a basic manufacturing method of the semiconductor device according to the third embodiment.

FIG. 16 is a cross-sectional view which schematically illustrates a part of the basic manufacturing method of the semiconductor device according to the third embodiment.

FIG. 17 is a cross-sectional view which schematically illustrates a part of the basic manufacturing method of the semiconductor device according to the third embodiment.

### DETAILED DESCRIPTION

In general, according to one embodiment, a semiconductor device includes a semiconductor substrate of a first conductivity type; a first region including a first well of a second conductivity type which is formed in the semiconductor substrate, a second well of the first conductivity type which is formed in the semiconductor substrate and on the first well, and a memory cell transistor which is formed on the second well; and a second region including a third well of the second conductivity type which is formed in the semiconductor substrate, and a first transistor of the first conductivity type which is formed on the third well. The semiconductor device includes a third region including a second transistor of the second conductivity type which is formed on the semiconductor substrate; and a fourth region including a fourth well of the second conductivity type which is formed in the semiconductor substrate, a fifth well of the first conductivity type which is formed in the semiconductor substrate and on the fourth well, and a third transistor of the second conductivity type which is formed on the fifth well. A position of each of bottom surfaces of the first well and the fourth well is lower than a position of a bottom surface of the third well, and the position of the bottom surface of the third well is lower than a position of each of bottom surfaces of the second well and the fifth well.

Embodiments will now be described in detail with reference to the accompanying drawings.

### First Embodiment

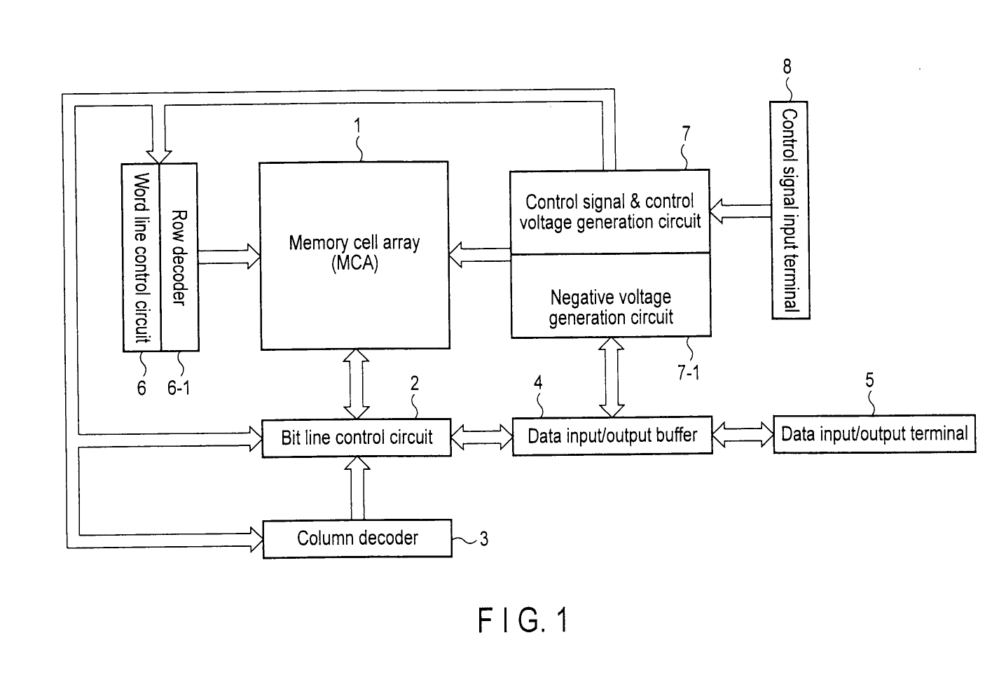

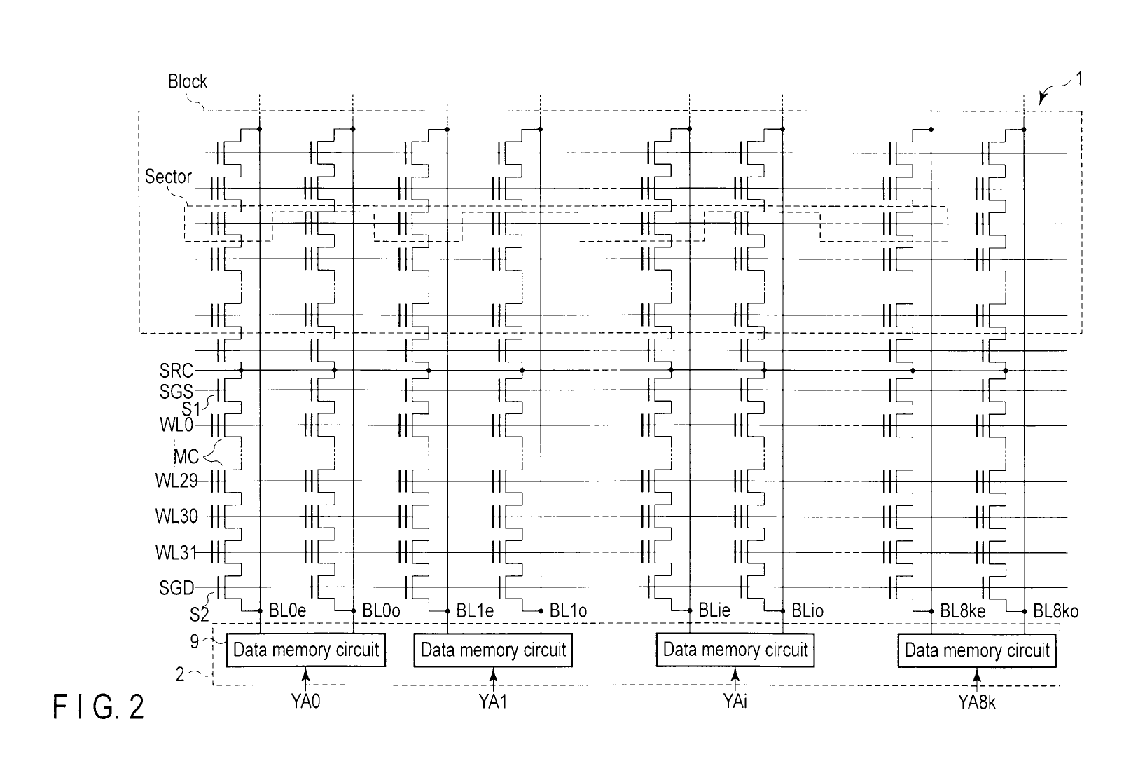

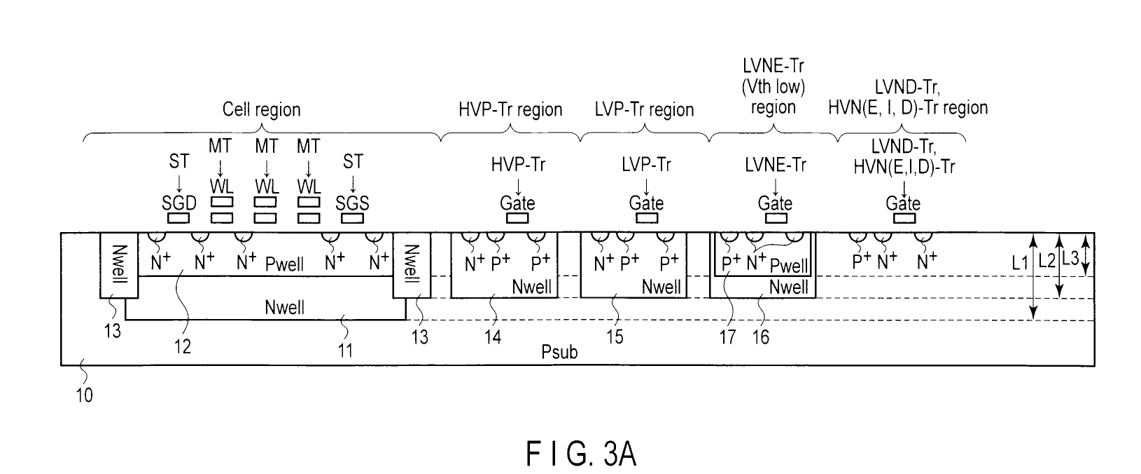

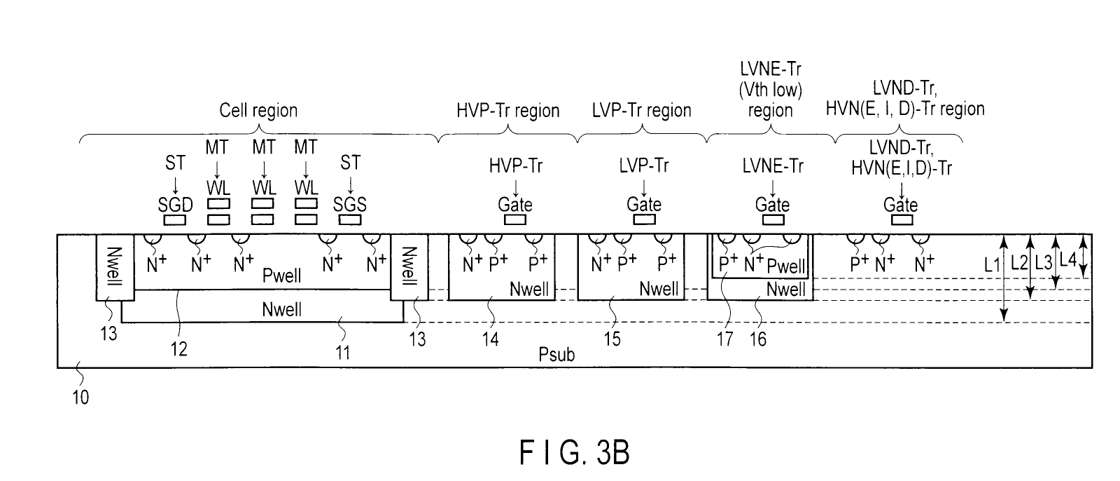

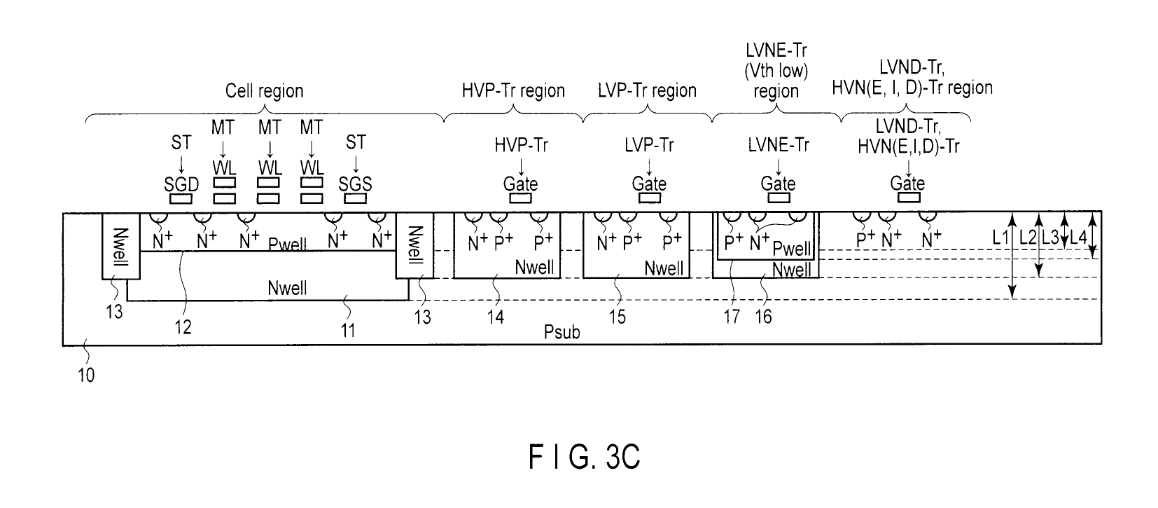

Referring to FIG. 1, the basic structure of a semiconductor device according to a first embodiment is described. FIG. 1 shows the structure of a semiconductor memory device according to the embodiment, to be more specific, a NAND flash memory which stores, e.g. 4-value (2-bit) data. FIG. 2 shows the structures of a memory cell array 1 and a bit line control circuit 2 shown in FIG. 1. FIG. 3A is a cross-sectional view showing the basic structure of the semiconductor device according to the first embodiment.

As shown in FIG. 1, the memory cell array 1 includes a plurality of bit lines, a plurality of word lines and a common source line. In the memory cell array 1, electrically data-rewritable memory cells, which are composed of, e.g. EEPROM cells, are arranged in a matrix. A bit line control circuit 2 for controlling the bit lines and a word line control circuit 6 are connected to the memory cell array 1.

The bit line control circuit 2 executes such operations as reading out data of memory cells in the memory cell array 1 via the bit lines, detecting the states of the memory cells in the memory cell array 1 via the bit lines, and writing data in the memory cells by applying a write control voltage to the memory cells in the memory cell array 1 via the bit lines. A column decoder 3 and a data input/output buffer 4 are connected to the bit line control circuit 2. Data memory circuits (to be described later) in the bit line control circuit 2 are selected by the column decoder 3. The data of the memory cell, which has been read out to the data memory circuit, is output to the outside from a data input/output terminal 5 via the data input/output buffer 4.

In addition, write data, which has been input to the data input/output terminal 5 from the outside, is input via the data input/output buffer 4 to the data memory circuit which has been selected by the column decoder 3.

The word line control circuit 6 includes a row decoder 6-1. The word line control circuit 6 selects a word line in the memory cell array 1 via the row decoder 6-1, and applies a voltage, which is necessary for read, write or erase, to the selected word line.

The memory cell array 1, bit line control circuit 2, column decoder 3, data input/output buffer 4 and word line control circuit 6 are connected to a control signal & control voltage generation circuit 7 and are controlled by this control signal & control voltage generation circuit 7. The control signal & control voltage generation circuit 7 is connected to a control signal input terminal 8 and is controlled by control signals, which are input from the outside via the control signal input terminal 8. The control signal & control voltage generation circuit 7 includes a negative voltage generation circuit 7-1 (to be described later). The negative voltage generation circuit 7-1 generates a negative voltage at times of data write and read.

The bit line control circuit 2, column decoder 3, word line control circuit 6 and control signal & control voltage generation circuit 7 constitute a write circuit and a read circuit.

As shown in FIG. 2, a plurality of NAND cells are disposed in the memory cell array 1. One NAND cell comprises memory cells MC, which are composed of, e.g. 32 EEPROMs that are connected in series; and select gates S1 and S2. The select gate S2 is connected to a bit line BL0e, and the select gate S1 is connected to a source line SRC. The control gates of the memory cells MC, which are disposed in each row, are commonly connected to the word line, WL0 to WL29, WL30, WL31. In addition, the select gates S2 are commonly connected to a select line SGD, and the select gates S1 are commonly connected to a select line SGS.

The bit line control circuit 2 includes a plurality of data memory circuits 9. A pair of bit lines (BL0e, BL0o), (BL1e, BL1o), . . . , (BLie, BLio), (BL8ke, BL8ko), are connected to each of the data memory circuits 9.

The memory cell array 1 includes a plurality of blocks, as indicated by a broken line. Each block comprises a plurality of NAND cells. For example, data is erased in units of a block. In addition, the erase operation is executed at the same time for two bit lines which are connected to the data memory circuit 9.

A plurality of memory cells (memory cells in a range surrounded by a broken line), which are disposed in every other bit line and are connected to one word line, constitute a sector. Data is written and read in units of the sector.

At the time of the read operation, program verify operation and program operation, one of the two bit lines (BLie, BLio), which are connected to the data memory circuit 9, is selected in accordance with an address signal (YA0, YA1, . . . , YAi, YA8k) which is supplied from the outside. In addition, one word line is selected in accordance with an external address.

As shown in FIG. 3A, the semiconductor device of the present embodiment includes a Cell region, an HVP-Tr region, an LVP-Tr region, an LVNE-Tr (Vth low) region, and an LVND-Tr, HVN(E, I, D)-Tr region.

For example, in a P-type semiconductor substrate (Psub) 10, N-type wells (Nwell) 11, 13, 14, 15 and 16 and P-type wells (Pwell) 12 and 17 are formed. A boundary (depth position) of the well refers to a position where an n-type impurity concentration and a p-type impurity concentration are substantially equal.

In the Cell region, memory cell transistors MT and select transistors ST are formed. Specifically, on the N-type well (also referred to simply as “N well”) 11 having a depth L1 from the surface of the semiconductor substrate 10 to the bottom surface of the N well 11, the P-type well (also referred to simply as “P well”) 12 having a depth L3 (L1>L3) from the surface of the semiconductor substrate 10 to the bottom surface of the P well 12 is formed, and the memory cells MT and select transistors ST are formed on the semiconductor substrate 10 and on the P well 12. In addition, the N well 13 having a depth L2 (L1>L2>L3) from the surface of the semiconductor substrate 10 to the bottom surface of the N well 13 is formed near side surfaces of the N well 11 and P well 12. As a result, the P well 12 is surrounded by the N wells 13 and 11 and is isolated from the P-type semiconductor substrate 10. In the P well 12, N-type diffusion layers (N⁺ layers) are formed as sources/drains of the memory cell transistors MT and select transistors ST. Charge accumulation layers are formed via a gate insulation film (not shown) on channel regions between the N⁺ layers and on the P well 12. Control gates (word lines WL) are formed on the charge accumulation layers via insulation films (not shown). Thereby, the memory cell transistors MT are formed on the P well 12. In addition, control gates (SGD, SGS) are formed via a gate insulation film (not shown) on channel regions between the N⁺ layers and on the P well 12, so as to sandwich a predetermined number of memory cell transistors MT. Thereby, at least two select transistors ST are formed on the P well 12 in such a manner as to sandwich the plural memory cell transistors MT.

In the HVP-Tr region, a high-voltage P-channel MOS transistor HVP-Tr, which constitutes a word line driving circuit, etc., is formed. Specifically, the N well 14 having a depth L2 from the surface of the semiconductor 10 to the bottom surface of the N well 14 is formed in the semiconductor substrate 10, and the high-voltage P-channel MOS transistor HVP-Tr is formed on the semiconductor substrate 10 and on the N well 14. P-type diffusion layers (P⁺ layers) are formed in the N well 14 as a source/drain of the high-voltage P-channel MOS transistor HVP-Tr. A control gate (Gate) is formed via a gate insulation film (not shown) on a channel region between the P⁺ layers and on the N well 14.

In the LVP-Tr region, a low-voltage P-channel MOS transistor LVP-Tr, which constitutes a part of the data memory circuit 9, is formed. Specifically, the N well 15 having a depth L2 from the surface of the semiconductor 10 to the bottom surface of the N well 15 is formed in the semiconductor substrate 10, and the low-voltage P-channel MOS transistor LVP-Tr is formed on the semiconductor substrate 10 and on the N well 15. P-type diffusion layers (P⁺ layers) are formed in the N well 15 as a source/drain of the low-voltage P-channel MOS transistor LVP-Tr. A control gate (Gate) is formed via a gate insulation film (not shown) on a channel region between the P⁺ layers and on the N well 15.

In the LVNE-Tr (Vth low) region, a low-voltage N-channel MOS transistor LVNE-Tr, which constitutes, for example, a part of the data memory circuit 9, is formed. Specifically, the P well 17 having a depth L3 from the surface of the semiconductor substrate 10 to the bottom surface of the P well 17 is formed in the N well 16 having a depth L2 from the surface of the semiconductor substrate 10 to the bottom surface of the N well 16. The low-voltage N-channel MOS transistor LVNE-Tr is formed on the semiconductor substrate 10 and on the P well 17. In addition, the P well 17 is surrounded by the N well 16 and is isolated from the P-type semiconductor substrate 10. In the P well 17, N-type diffusion layers (N⁺ layers) are formed as a source/drain of the low-voltage N-channel MOS transistor LVNE-Tr. A control gate (Gate) is formed via a gate insulation film (not shown) on a channel region between the N⁺ layers and on the P well 17.

In the LVND-Tr, HVN(E, I, D)-Tr region, a low-voltage N-channel MOS transistor LVND-Tr or a high-voltage N-channel MOS transistor HVN(E, I, D)-Tr is formed on the semiconductor substrate 10. On the semiconductor substrate 10, N-type diffusion layers (N⁺ layers) are formed as a source/drain of the low-voltage N-channel MOS transistor LVND-Tr or high-voltage N-channel MOS transistor HVN(E, I, D)-Tr. A control gate (Gate) is formed via a gate insulation film (not shown) on a channel region between the N⁺ layers and on the semiconductor substrate 10. The threshold voltage of the high-voltage N-channel MOS transistor HVN(E, I, D)-Tr is set to be: high-voltage N-channel MOS transistor HVN(E)-Tr>high-voltage N-channel MOS transistor HVN(I)-Tr>high-voltage N-channel MOS transistor HVN(D)-Tr. In addition, the impurity concentration of the P well 17 is higher than the impurity concentration of the P well 12. The reason for this is that the breakdown voltage of the diffusion layer and P well 12 needs to be raised in the Cell region and the threshold voltage of the low-voltage N-channel MOS transistor LVNE-Tr needs to be raised to some degree in the LVNE-Tr (Vth low) region.

The high-voltage transistors HVN-Tr and HVP-Tr have thicker gate oxide films than the low-voltage transistors LVP-Tr and LVN-Tr.

As shown in FIG. 3B, there is a case in which the depth of the P well 17 from the surface of the semiconductor substrate 10 to the bottom surface of the p well 17 is L4 which is less than L3. In this case, the relationship, L1>L2>L3>L4, is established. Besides, as shown in FIG. 3C, there is a case in which the depth of the P well 17 from the surface of the semiconductor substrate 10 to the bottom surface of the p well 17 is L4 which is greater than L3 and is less than L2. In this case, the relationship, L1>L2>L4>L3, is established.

Although not shown, the respective regions are isolated by element isolation regions which are formed, for example, at boundaries of the respective regions and in surface regions of the semiconductor substrate 10. An example of the element isolation region is an STI (shallow trench isolation) which is formed such that an insulation film is buried in a trench which is formed, for example, in a surface region of the semiconductor substrate 10.

### (Read Operation)

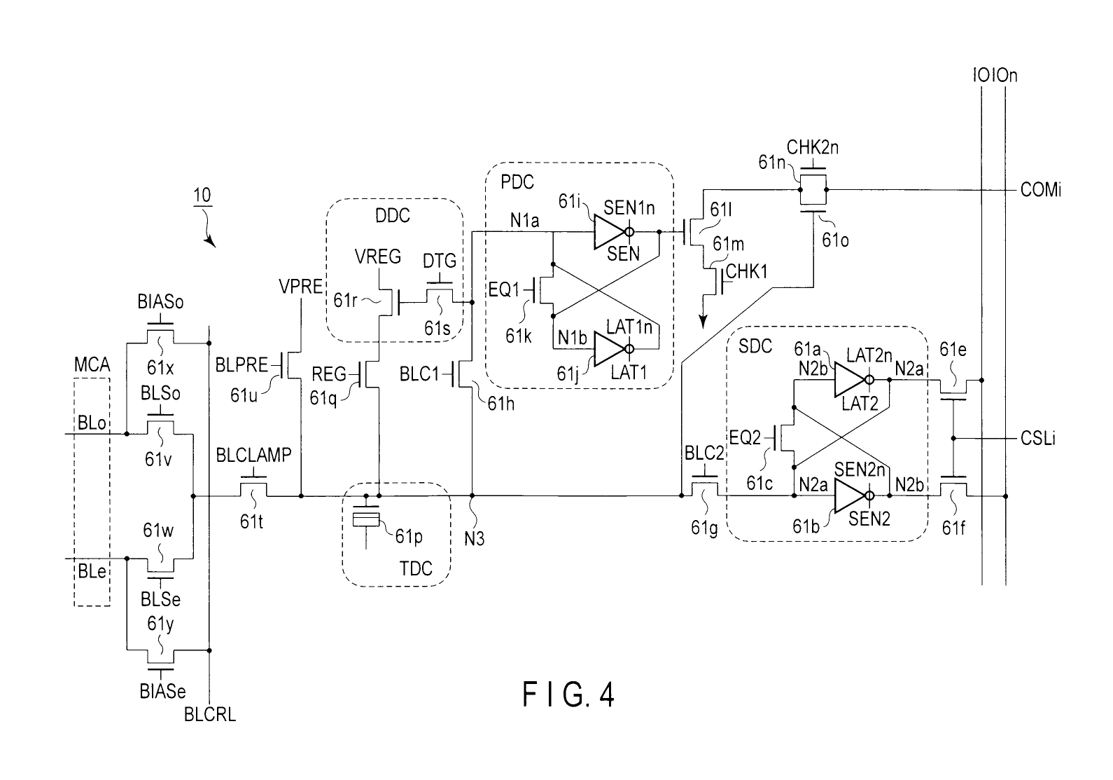

FIG. 4 is a circuit diagram showing an example of the data memory circuit 9 shown in FIG. 2.

The data memory circuit 9 includes a primary data cache (PDC), a secondary data cache (SDC), a dynamic data cache (DDC) and a temporary data cache (TDC). The SDC, PDC and DDC hold input data at a time of write, hold read data at a time of read, temporarily hold data at a time of verify, and are used for an operation of internal data at a time of storing multi-value data. The TDC amplifies and temporarily holds data of a bit line at a time of reading data, and is used for an operation of internal data at a time of storing multi-value data.

The SDC is composed of clocked inverter circuits 61a and 61b which constitute a latch circuit, and transistor 61c. The transistor 61c is connected between an input terminal of the clocked inverter circuit 61a and an input terminal of the clocked inverter circuit 61b. A signal EQ2 is supplied to the gate of the transistor 61c. A node N2a of the SDC is connected to an input/output data line 10 via a column select transistor 61e, and a node N2b is connected to an input/output data line IOn via a column select transistor 61f. The gates of the transistors 61e and 61f are supplied with a column select signal CSLi. The node N2a of the SDC is connected to a node N1a of the PDC via transistors 61g and 61h. The gate of the transistor 61g is supplied with a signal BLC2, and the gate of the transistor 61h is supplied with a signal BLC1.

The PDC is composed of clocked inverter circuits 61i and 61j, and a transistor 61k. The transistor 61k is connected between an input terminal of the clocked inverter circuit 61i and an input terminal of the clocked inverter circuit 61j. The gate of the transistor 61k is supplied with a signal EQ1. A node N1b of the PDC is connected to the gate of a transistor 61l. One end of the current path of the transistor 61l is grounded via a transistor 61m. The gate of the transistor 61m is supplied with a signal CHK1. The other end of the current path of the transistor 61l is connected to one end of the current path of each of transistors 61n and 610 which constitute a transfer gate. The gate of the transistor 61n is supplied with a signal CHK2n. The gate of the transistor 610 is connected to a connection node N3 of the transistors 61g and 61h. The other end of the current path of each of the transistors 61n and 610 is connected to a signal line COMi. The signal line COMi is a signal line common to all data memory circuits 9. The level of the signal line COMi indicates whether verify of all data memory circuits 9 has been completed. Specifically, as will be described later, when verify is completed, the node N1b of the PDC is set at a low level. In this state, if the signals CHK1 and CHK2n are set at a high level, the level of the signal line COMi is set at the high level in the case where the verify of all data memory circuits 9 has been completed.

The TDC is composed of, e.g. a MOS capacitor 61p. The capacitor 61p is connected between the connection node N3 of the transistors 61g and 61h, and the ground. In addition, the DDC is connected to the connection node N3 via a transistor 61q. The gate of the transistor 61q is supplied with a signal REG.

The DDC is composed of transistors 61r and 61s. A signal VREG is supplied to one end of the current path of the transistor 61r, and the other end of the current path of the transistor 61r is connected to the current path of the transistor 61q. The gate of the transistor 61r is connected to the node N1a of the PDC via the transistor 61s. A signal DTG is supplied to the gate of the transistor 61s.

Moreover, the connection node N3 is connected to one end of the current path of each of transistors 61t and 61u. The other end of the current path of the transistor 61u is supplied with a signal VPRE, and the gate of the transistor 61u is supplied with BLPRE. The gate of the transistor 61t is supplied with a signal BLCLAMP. The other end of the current path of the transistor 61t is connected to one end of a bit line BLo via a transistor 61v, and to one end of a bit line BLe via a transistor 61w. The other end of the bit line BLo is connected to one end of the current path of a transistor 61x. The gate of the transistor 61x is supplied with a signal BIASo. The other end of the bit line BLe is connected to one end of the current path of a transistor 61y. The gate of the transistor 61y is supplied with a signal BIASe. The other end of the current path of each of the transistors 61x and 61y is supplied with a signal BLCRL. The transistors 61x and 61y are turned on complementarily to the transistors 61v and 61w in accordance with the signals BIASo and BIASe, and supply the potential of the signal BLCRL to a non-selected bit line.

The transistors disposed in the data memory circuit 9 are, for example, the low-voltage N-channel MOS transistors LVNE-Tr and LVND-Tr, and the low-voltage P-channel MOS transistor LVP-Tr.

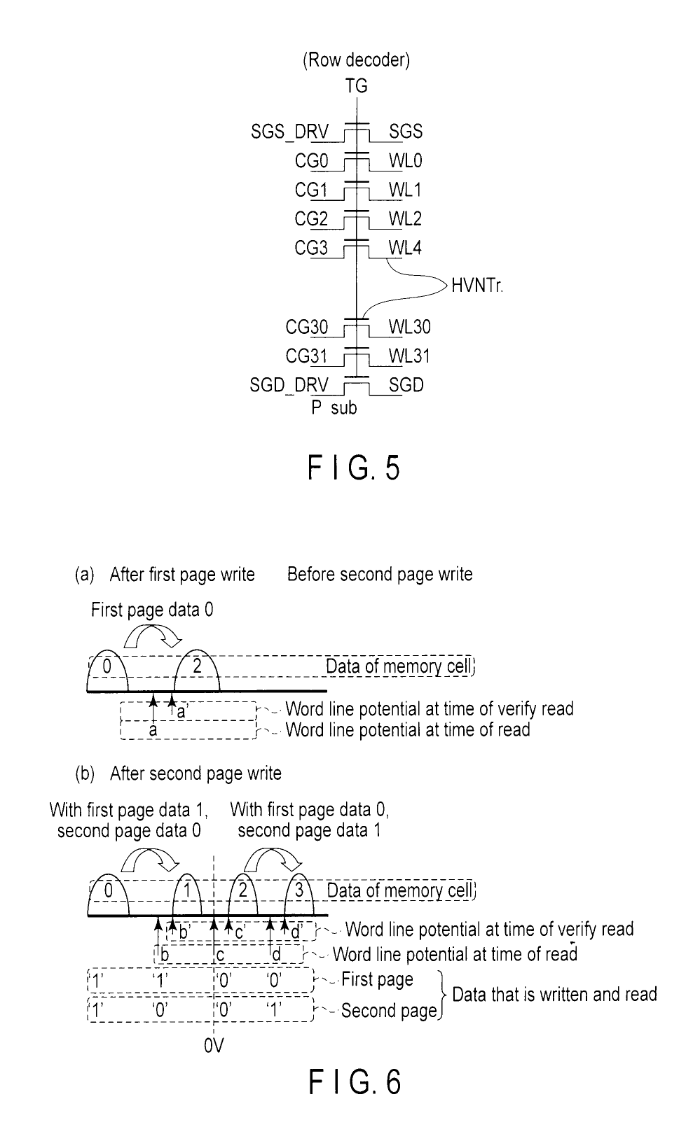

FIG. 5 shows a transfer gate which constitutes a part of the row decoder 6-1. This transfer gate is composed of a plurality of the above-described high-voltage N-channel MOS transistors HVN(E)-Tr. The transistors HVN(E)-Tr are supplied at one end with voltages SGS_DRV, CG0 to CG31, and SGD_DRV, and are connected at the other end to the select line SGS, word lines WL0 to WL31 and select line SGD. A signal TG is supplied to the gate of each transistor HVN(E)-Tr. The transistors HVN(E)-Tr of each selected block are turned on in response to the signal TG, thereby supplying a predetermined voltage to the word lines WL0 to WL31 of the cells.

Next, the read operation is described in detail.

As shown in part (a) of FIG. 6, after first page write, the data of memory cells are “0” or “2”. Thus, these data can be read by executing a read operation by supplying an intermediate level “a” of the data to the word line. As shown in part (b) of FIG. 6, after second page write, the data of memory cells are any one of “0”, “1”, “2” and “3”. These data can be read by executing a read operation by supplying an intermediate voltage level “b”, “c” or “d” of these data to the word line. In the present embodiment, for example, the voltage levels “a” and “b” are negative voltages.

The well of memory cells (P-well region 12 in FIG. 3A, FIG. 3B and FIG. 3C), the source line and the non-selected bit line are set at Vss (ground potential=0 V). The P-type semiconductor substrate 10 is set at a negative potential (e.g. −2 V), and the transfer gate (shown in FIG. 5) of the non-selected block is turned off. Thereby, the word line of the non-selected block is set in the floating state, and the select gate is set at Vss. In addition, the transfer gate of the selected block is turned on. Thereby, the selected word line of the selected block is set at a potential (e.g. −2 V to 3 V) at a time of read, the non-selected word line of the selected block is set at Vread (e.g. 5 V), and the select gate SGD of the selected block is set at Vsg (VDD+Vth, e.g. 2.5 V+Vth). When the potential at the time of read is not negative, the P-type semiconductor substrate 10 may be set at Vss.

In the case where the potential at the time of read is negative, a negative potential is applied to the diffusion layer N⁺ of the transfer gate. Thus, by also applying a negative potential to the P-type semiconductor substrate 10, it is possible to prevent a forward current from flowing between the diffusion layer of the high-voltage N-channel MOS transistor HVN(E)-Tr and the P-type semiconductor substrate 10. In this case, it is thinkable that the high-voltage N-channel MOS transistor HVN(E)-Tr, like the low-voltage N-channel MOS transistor LVNE-Tr, is formed on the P well 17 which is surrounded by the N well 16. However, at the time of write, a high breakdown voltage of 20 V or more is applied to the diffusion layer of the high-voltage N-channel MOS transistor HVN(E)-Tr. As a result, the breakdown voltage between the high-voltage N-channel MOS transistor HVN(E)-Tr and the P well 17 cannot be withstood, and a large current may possibly flow to the P well 17.

Thus, in the present embodiment, the high-voltage N-channel MOS transistor HVN(E)-Tr is formed on the P-type semiconductor substrate 10, and a negative potential is applied to the P-type semiconductor substrate 10. Thereby, the negative threshold voltage distribution can be read.

Next, the signal VPRE of the data memory circuit 9 shown in FIG. 4 is set at Vdd (e.g. 2.5 V), the signal BLPRE is set at Vsg (Vdd+Vth), the signal BLCLAMP is set at, e.g. (0.6 V+Vth), and the bit line is precharged to, e.g. 0.6 V. Then, the source-side select line SGS of the cell is set at Vdd. When the threshold voltage of the memory cell is higher than the potential at the time of read, the cell is turned off and thus the bit line remains at the high level. On the other hand, when the threshold voltage of the memory cell is lower than the potential at the time of read, the cell is turned on and thus the bit line potential is set at Vss.

Subsequently, the signal BLPRE of the data memory circuit 9 shown in FIG. 4 is once set at Vsg (Vdd+Vth), and the node N3 of the TDC is precharged to Vdd, and thereafter the BLCLAMP is set at, e.g. (0.45 V+Vth). The node N3 of the TDC is at the low level when the bit line potential is lower than 0.45 V, and is at the high level when the bit line potential is higher than 0.45 V. After the BLCLAMP is set at Vss, the signal BLC1 is set at Vsg (Vdd+Vth), and the potential of the TDC is read into the PDC. Accordingly, the PDC is at the low level when the threshold voltage of the cell is lower than the word line potential, and the PDC is at the high level when the threshold voltage of the cell is higher than the word line potential.

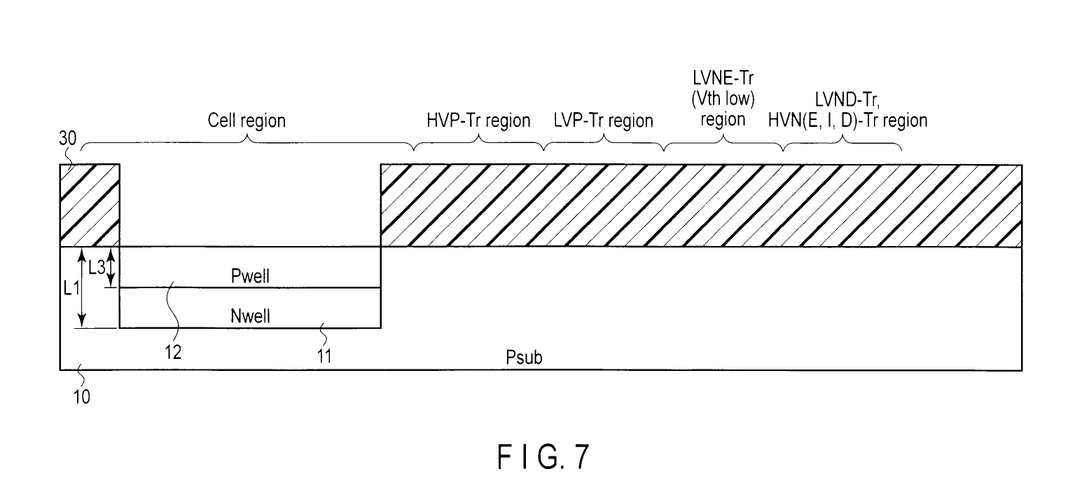

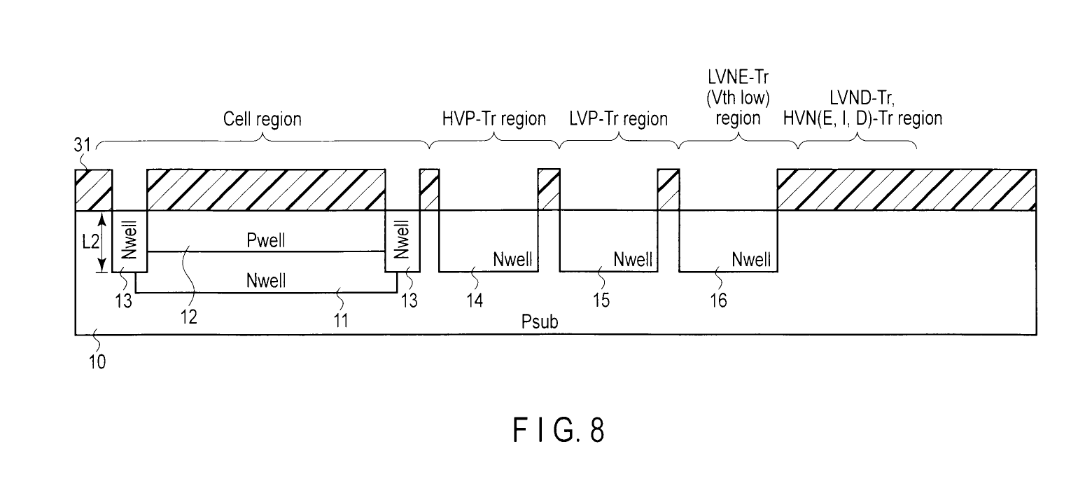

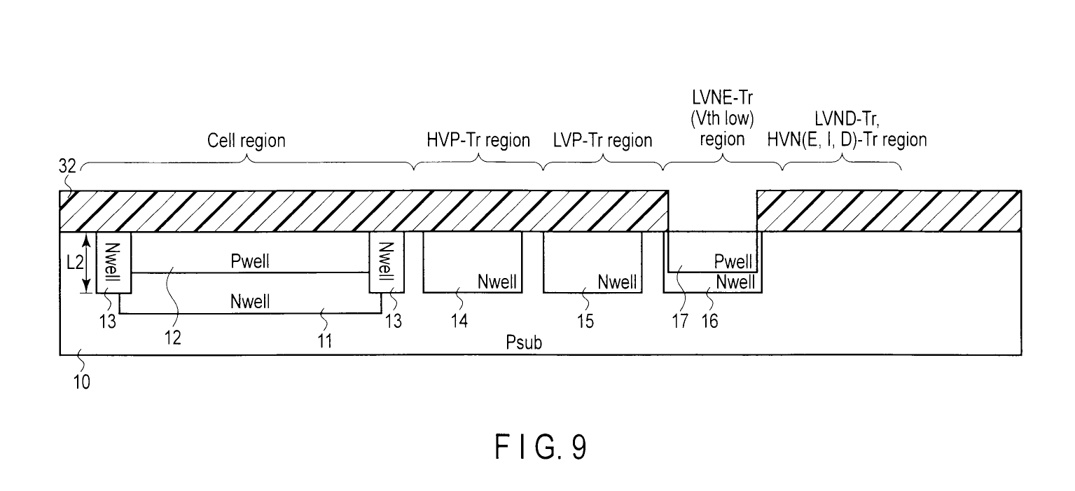

Next, referring to FIG. 3A and FIGS. 7 to 9, a basic manufacturing method of the semiconductor device according to the first embodiment is described. FIG. 7, FIG. 8 and FIG. 9 are cross-sectional views which schematically illustrate the basic manufacturing method of the semiconductor device according to the first embodiment.

To start with, as shown in FIG. 7, a photoresist, for example, is coated on a P-type semiconductor substrate (silicon substrate) 10, and thereby a resist layer 30 is formed. The resist layer 30 is exposed/developed, and an opening is formed for patterns of an N well 11 and a P well 12. Using the resist layer 30 as a mask, impurities (e.g. phosphorus or arsenic) for forming an N-type well are doped in the semiconductor substrate 10. At this time, the impurities are doped such that the bottom surface of the N-type well 11 is positioned at a depth L1 from the surface of the semiconductor substrate 10. Then, using the resist layer 30 as a mask, impurities (e.g. boron) for forming a P-type well 12 are doped in the semiconductor substrate 10. At this time, the impurities are doped such that the bottom surface of the P-type well 12 is positioned at a depth L3 (L1>L3) from the surface of the semiconductor substrate 10.

Thereby, the N well 11, which has the depth L1 from the surface of the semiconductor substrate 10 to the bottom surface of the N well 11, and the P well 12, which has the depth L3 (L1>L3) from the surface of the semiconductor substrate 10 to the bottom surface of the P well 12, are formed in the semiconductor substrate 10. The thickness of the resist layer 30 is, for example, about 3 μm, and is greater than the thickness of each of resist layers 31 and 32, which will be described later. The reason for this is that the energy for the doping (ion implantation) at the time of forming the N well 11 is large.

Next, as shown in FIG. 8, the resist layer 30 is removed, and a photoresist, for example, is coated on the semiconductor substrate 10 and thereby a resist layer 31 is formed. The resist layer 31 is exposed/developed, and openings are formed for patterns of N wells 13, 14, 15 and 16. The N well 13 is formed near a boundary between the P well 12 and the semiconductor substrate 10. Specifically, a part of a side portion of the N well 13 overlaps the N well 11 and P well 12. Using the resist layer 31 as a mask, impurities for forming an N-type well are doped in the semiconductor substrate 10. At this time, the impurities are doped such that the bottom surface of the N-type well is positioned at a depth L2 (L1>L2>L3) from the surface of the semiconductor substrate 10. Thereby, N wells 13, 14, 15 and 16, each having the depth L2 from the surface of the semiconductor substrate 10 to the bottom surface thereof, are formed in the semiconductor substrate 10.

Next, as shown in FIG. 9, the resist layer 31 is removed, and a photoresist, for example, is coated on the semiconductor substrate 10 and thereby a resist layer 32 is formed. The resist layer 32 is exposed/developed, and an opening is formed for a pattern of a P well 17. When the LVNE-Tr (Vth low) region is viewed from above, the pattern of the P well 17 is opened so as to be included in the pattern of the N well 16. The P well 17 is formed in the N well 16 in an overlapping implantation fashion. Using the resist layer 32 as a mask, impurities for forming a P-type well are doped in the semiconductor substrate 10. At this time, the impurities are doped such that the bottom surface of the P-type well is positioned at the depth L3 or less from the surface of the semiconductor substrate 10. Thereby, the P well 17 having the depth L3 or less from the surface of the semiconductor substrate 10 to the bottom surface of the P well 17 is formed in the N well 16. As a result, the P well 17 is surrounded by the N well 16 and is isolated from the P-type semiconductor substrate 10. The amount of impurity implantation for forming the P well 17 is greater than the amount of impurity implantation for forming the P well 12. The bottom surface of the P-type well 17 may also be positioned at less than the depth L2 from the surface of the semiconductor substrate 10 in some cases.

Next, as shown in FIG. 3A, using a well-known manufacturing method, memory cell transistors MT, select transistors ST and N⁺ layers are formed in the P well 12 of the Cell region. A high-voltage P-channel MOS transistor HVP-Tr, P⁺ layers and an N⁺ layer are formed in the N well 14 of the HVP-Tr region. A low-voltage P-channel MOS transistor LVP-Tr, P⁺ layers and an N⁺ layer are formed in the N well 15 of the LVP-Tr region. A low-voltage N-channel MOS transistor LVNE-Tr, N⁺ layers and a P⁺ layer are formed in the P well 17 of the LVNE-Tr (Vth low) region. A low-voltage N-channel MOS transistor LVND-Tr or a high-voltage N-channel MOS transistor HVN(E, I, D)-Tr is formed in the LVND-Tr, HVN(E, I, D)-Tr region of the semiconductor substrate 10. In addition, element isolation regions are formed between the respective regions.

According to the above-described embodiment, the N well 16 of the LVNE-Tr (Vth low) region is formed at the same time as the N well 13 of the Cell region, the N well 14 of the HVP-Tr region and the N well 15 of the LVP-Tr region. Then, the resist is formed on the semiconductor substrate 10 in the Cell region, the HVP-Tr region, the LVP-Tr region, and the LVND-Tr & HVN(E, I, D)-Tr region. Using this resist as a mask, the P well 17 of the LVNE-Tr (Vth low) region is formed. In this manner, the semiconductor device including the low-voltage N-channel transistor LVNE-Tr of the double-well structure can easily be formed. As a result, even in the case where a negative voltage is applied to the gate of the selected cell and the word line is set at a negative potential, the flow of a forward current can be prevented when the P-type semiconductor substrate 10 is set a negative potential. Thus, the semiconductor substrate can quickly be charged to a negative potential, and the electric current consumption can be reduced. As a result, the semiconductor device with good quality can be obtained.

In a case where N wells 14, 15 and 16 are formed at the same time as the N well 11, it is necessary to increase the circuit area in consideration of a displacement of patterns by shadowing due to the thickness of the resist layer 30 (i.e. a phenomenon in which impurities are not doped in the shadow of the resist, which occurs when the impurities are implanted in the substrate surface in an oblique direction inclined from the vertical direction). However, the N wells 14, 15 and 16 are not formed when the N well 11 is formed, and the N wells 14, 15 and 16 are formed by using a resist which is thinner than the resist layer 30. Thus, the displacement of patterns due to the shadowing of the resist can be suppressed, and implantation can be performed with high precision. As a result, the circuit area can be reduced.

### Second Embodiment

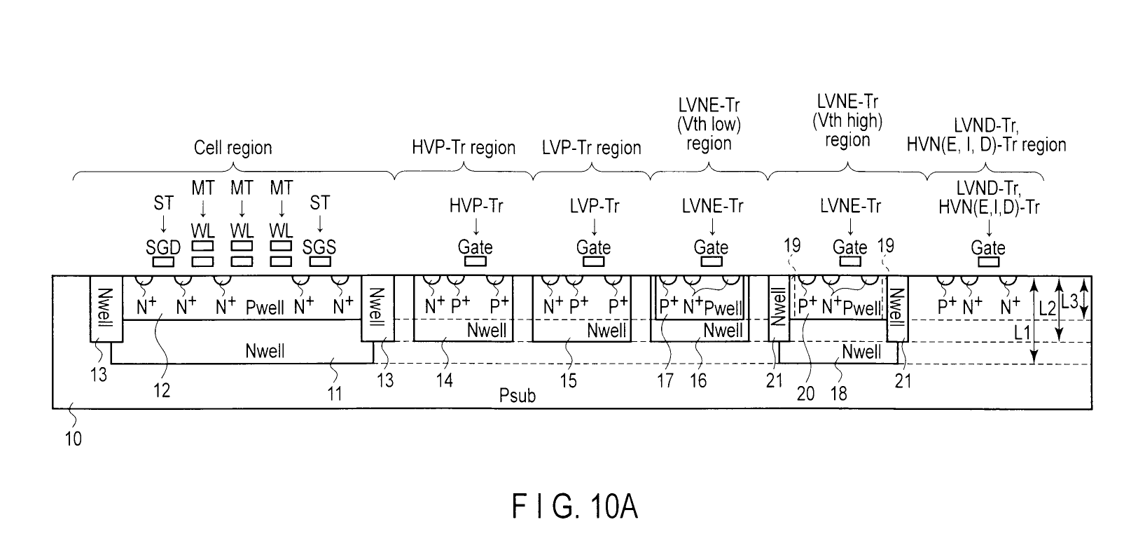

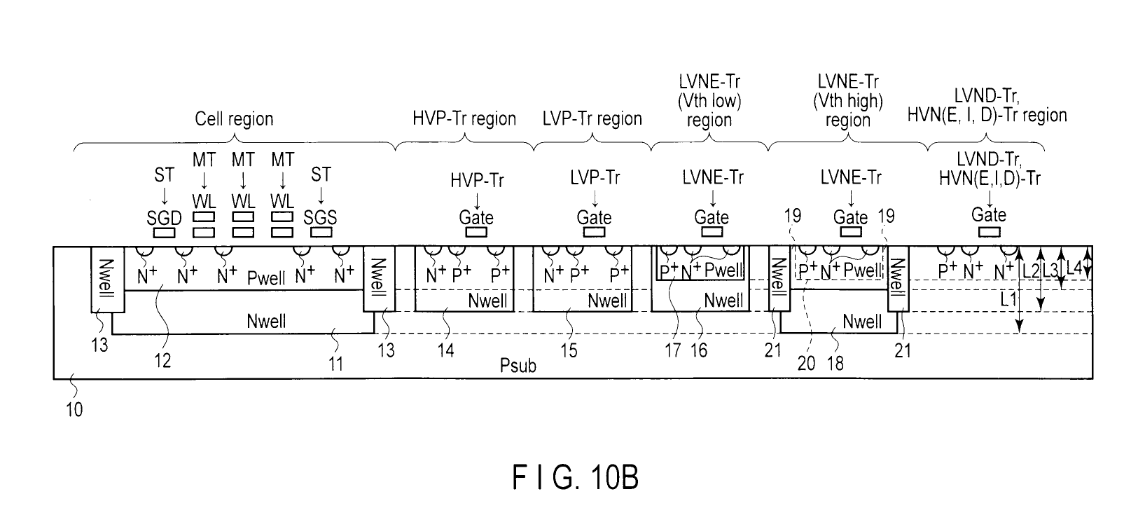

Referring to FIG. 10A and FIG. 10B, the basic structure of a semiconductor device according to a second embodiment is described. FIG. 10A and FIG. 10B are cross-sectional views showing the basic structure of the semiconductor device according to the second embodiment. The basic structure and the basic manufacturing method of this embodiment are the same as those of the above-described first embodiment. Thus, a description of parts, which can be easily guessed from the above-described matters and examples, is omitted.

As shown in FIG. 10A, the semiconductor device according to the second embodiment further includes a LVNE-Tr (Vth high) region, in addition to the respective regions of the semiconductor device according to the first embodiment. Specifically, the semiconductor device of the present embodiment includes a Cell region, an HVP-Tr region, an LVP-Tr region, an LVNE-Tr (Vth low) region, an LVNE-Tr (Vth high) region, and an LVND-Tr, HVN(E, I, D)-Tr region.

For example, in a P-type semiconductor substrate (Psub) 10, N wells 11, 13, 14, 15, 16, 18 and 21 and P wells 12, 17, 19 and 20 are formed.

In the LVNE-Tr (Vth high) region, a low-voltage N-channel MOS transistor LVNE-Tr, which constitutes, for example, a part of the data memory circuit 9, is formed. Specifically, the P well 19, which has a depth L3 (L1>L3) from the surface of the semiconductor substrate 10 to the bottom surface of the P well 19, is formed on the N well 18 which has a depth L1 from the surface of the semiconductor substrate 10 to the bottom surface of the N well 18. The P well 20, which has a higher impurity concentration than the P well 19, is formed in the P well 19. In addition, the N well 21 having a depth L2 (L1>L2>L3) from the surface of the semiconductor substrate 10 to the bottom surface of the N well 21 is formed near a boundary at side surfaces of the N well 18 and P well 19. The P wells 19 and 20 are surrounded by the N well 21 and N well 18, and are isolated from the P-type semiconductor substrate 10. Specifically, although a part of the side portion of the P well 19 overlaps the N well 21, the P well 20 and N well 21 do not overlap. As a result, the P-type impurity concentration of the P well 20 is high. Further, a low-voltage N-channel MOS transistor LVNE-Tr is formed on the semiconductor substrate 10 and on the P well 20. In the P well 20, N-type diffusion layers (N⁺ layers) are formed as a source/drain of the low-voltage N-channel MOS transistor LVNE-Tr. A control gate (Gate) is formed via a gate insulation film (not shown) on a channel region between the N⁺ layers and on the P well 20.

In the meantime, the threshold of the low-voltage N-channel MOS transistor LVNE-Tr in the LVNE-Tr (Vth low) region is substantially equal to the threshold of the low-voltage N-channel MOS transistor LVNE-Tr in the LVNE-Tr (Vth high) region. However, owing to the difference in impurity concentration between the P well 17 and P well 20, the threshold of the low-voltage N-channel MOS transistor LVNE-Tr in the LVNE-Tr (Vth low) region and the threshold of the low-voltage N-channel MOS transistor LVNE-Tr in the LVNE-Tr (Vth high) region are different by about 0.2 V.

As shown in FIG. 10B, in the LVNE-Tr (Vth high) region, the depth from the surface of the semiconductor substrate 10 to the bottom surface of the P well 19 is L3. On the other hand, in the LVNE-Tr (Vth high) region, the depth from the surface of the semiconductor substrate 10 to the bottom surface of the P well 20 is L4 which is less than L3. Specifically, the P well 20 is surrounded by the P well 19, and the P well 20 is not in contact with the N well 18 or 21. As a result, the gradient of the impurity concentrations of the N well 18 and P well 20 can be decreased. As a result, a leak current between the N well 18 and P well 20 can be decreased.

In the meantime, the depth of the P well 17 from the surface of the semiconductor substrate 10 to the bottom surface of the P well 17 is also substantially equal to L4.

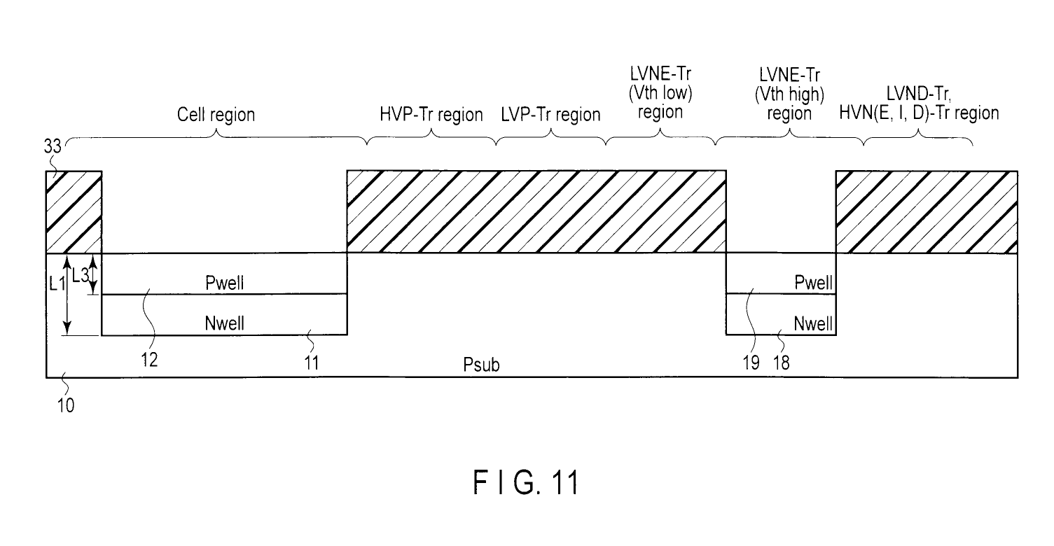

Next, referring to FIGS. 10A and 10B and FIGS. 11 to 13, a basic manufacturing method of the semiconductor device according to the second embodiment is described. FIGS. 11 to 13 are cross-sectional views which schematically illustrate the basic manufacturing method of the semiconductor device according to the second embodiment.

To start with, as shown in FIG. 11, a photoresist, for example, is coated on a P-type semiconductor substrate 10, and thereby a resist layer 33 is formed. The resist layer 33 is exposed/developed, and openings are formed for patterns of N wells 11 and 18 and P wells 12 and 19. Using the resist layer 33 as a mask, impurities (e.g. phosphorus or arsenic) for forming N-type wells are doped in the semiconductor substrate 10. At this time, the impurities are doped such that the bottom surfaces of the N-type wells are positioned at a depth L1 from the surface of the semiconductor substrate 10. Then, using the resist layer 33 as a mask, impurities (e.g. boron) for forming P-type wells are doped in the semiconductor substrate 10. At this time, the impurities are doped such that the bottom surfaces of the P-type wells are positioned at a depth L3 (L1>L3) from the surface of the semiconductor substrate 10. Thereby, the N well 11, which has the depth L1 from the surface of the semiconductor substrate 10 to the bottom surface of the N well 11, and the P well 12, which is located on the N well 11 and has the depth L3 from the surface of the semiconductor substrate 10 to the bottom surface of the P well 12, are formed in the semiconductor substrate 10. In addition, the N well 18, which has the depth L1 from the surface of the semiconductor substrate 10 to the bottom surface of the N well 18, and the P well 19, which is located on the N well 18 and has the depth L3 from the surface of the semiconductor substrate 10 to the bottom surface of the P well 19, are formed. The thickness of the resist layer 33 is, for example, about 3 μm, and is greater than the thickness of each of resist layers 34 and 35, which will be described later. The reason for this is that the energy for the doping at the time of forming the N wells 11 and 18 is large.

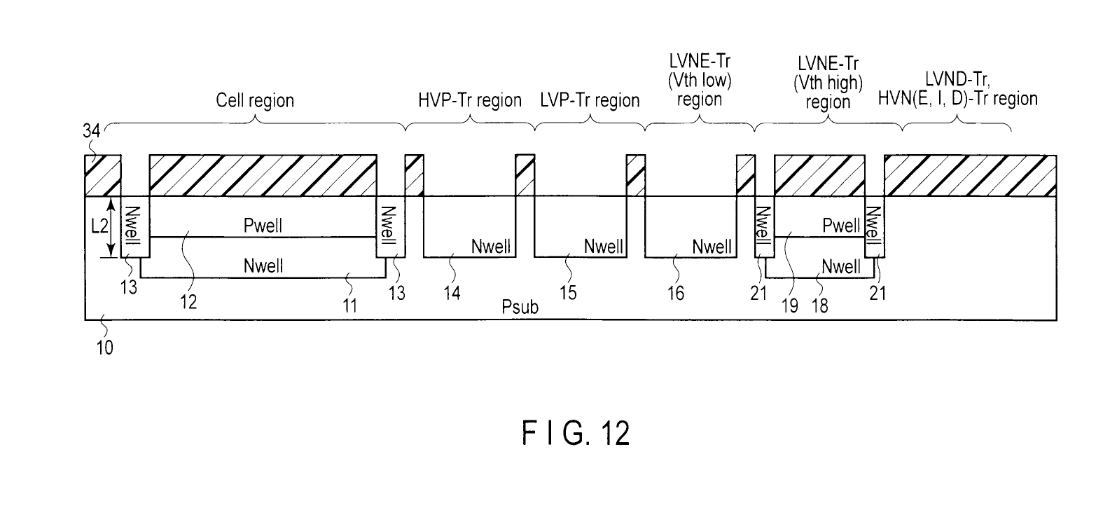

Next, as shown in FIG. 12, the resist layer 33 is removed, and a photoresist, for example, is coated on the semiconductor substrate 10 and thereby a resist layer 34 is formed. The resist layer 34 is exposed/developed, and openings are formed for patterns of N wells 13, 14, 15, 16 and 21. The N well 13 is formed at a boundary plane between the P well 12 and the semiconductor substrate 10. In addition, the N well 21 is formed near a boundary plane between the P well 19 and the semiconductor substrate 10. Using the resist layer 34 as a mask, impurities for forming N-type wells are doped in the semiconductor substrate 10. At this time, the impurities are doped such that the bottom surfaces of the N-type wells are positioned at a depth L2 (L1>L2>L3) from the surface of the semiconductor substrate 10. Thereby, N wells 13, 14, 15, 16 and 21, each having the depth L2 from the surface of the semiconductor substrate 10 to the bottom surface thereof, are formed in the semiconductor substrate 10.

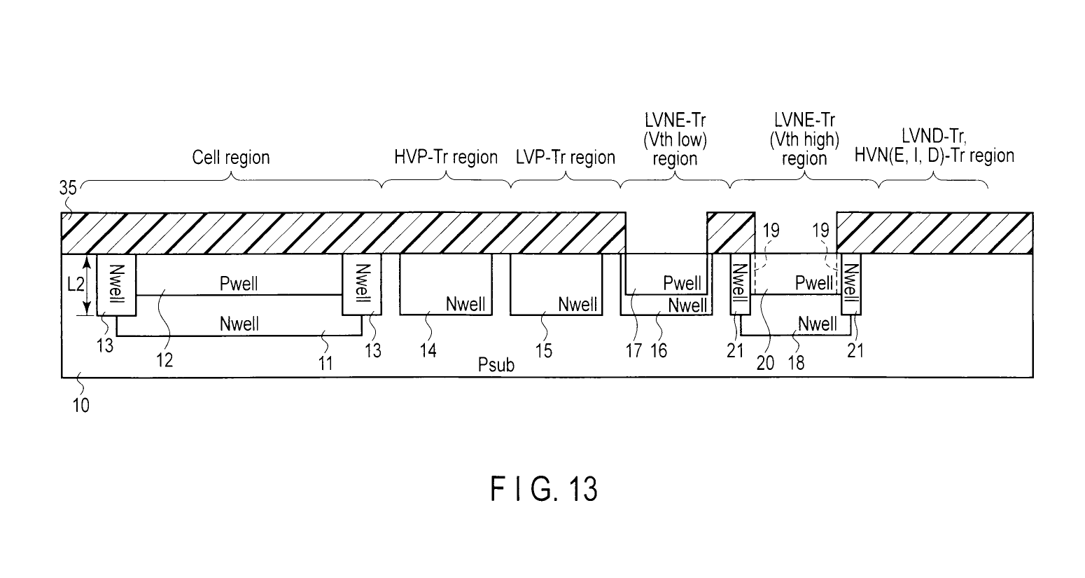

Next, as shown in FIG. 13, the resist layer 34 is removed, and a photoresist, for example, is coated on the semiconductor substrate 10 and thereby a resist layer 35 is formed. The resist layer 35 is exposed/developed, and openings are formed for patterns of a P well 17 and a P well 20. The P well 17 is formed in the N well 16. The P well 20 is formed in the P well 19. Specifically, the P well 20 is formed by double implantation of the steps drawn in FIG. 11 and FIG. 13. When the LVNE-Tr (Vth high) region is viewed from above, the pattern of the P well 20 is opened so as to be included in the pattern of the P well 19. Specifically, the N well 21 is not in contact with the P well 20. As a result, the P well 20 and N well 21, which have high impurity concentrations, do not come in contact. Thus, the gradient of impurity concentrations between the N well 21 and P well 20 can be decreased, and a leak current can be reduced. Using the resist layer 35 as a mask, impurities for forming P-type wells are doped in the semiconductor substrate 10. At this time, the impurities are doped such that the bottom surface of the P-type wells are positioned at the depth L3 or less from the surface of the semiconductor substrate 10. Thereby, the P well 17 having the depth L3 or less from the surface of the semiconductor substrate 10 to the bottom of the P well 17 is formed in the N well 16, and the P well 20 having the depth L3 or less from the surface of the semiconductor substrate 10 to the bottom of the P well 20 is formed in the P well 19.

In the case of forming the P wells 17 and 20 shown in FIG. 10B, the acceleration of impurities for forming the P-type wells is adjusted so that the depth of each of the P wells 17 and 20 from the surface of the semiconductor substrate 10 to the bottom surface thereof may become L4 which is less than L3.

Next, as shown in FIG. 10A, using a well-known manufacturing method, memory cell transistors MT, select transistors ST and N⁺ layers are formed in the P well 12 of the Cell region. A high-voltage P-channel MOS transistor HVP-Tr, P⁺ layers and an N⁺ layer are formed in the N well 14 of the HVP-Tr region. A low-voltage P-channel MOS transistor LVP-Tr, P⁺ layers and an N⁺ layer are formed in the N well 15 of the LVP-Tr region. A low-voltage N-channel MOS transistor LVNE-Tr, N⁺ layers and a P⁺ layer are formed in the P well 17 of the LVNE-Tr (Vth low) region. A low-voltage N-channel MOS transistor LVNE-Tr, N⁺ layers and a P⁺ layer are formed in the P well 20 of the LVNE-Tr (Vth high) region. A low-voltage N-channel MOS transistor LVND-Tr or a high-voltage N-channel MOS transistor HVN(E, I, D)-Tr is formed in the LVND-Tr, HVN(E, I, D)-Tr region of the semiconductor substrate 10. In addition, element isolation regions are formed between the respective regions.

According to the above-described embodiment, the N well 18 of the LVNE-Tr (Vth high) region is formed at the same time as the N well 11 of the Cell region, and the P well 19 is formed at the same time as the P well 12 of the Cell region. The N well 21 is formed at the same time as the N well 13 of the Cell region, the N well 14 of the HVP-Tr region, the N well 15 of the LVP-Tr region, and the N well 16 of the LVNE-Tr (Vth low) region. The P well 20 is formed at the same time as the P well 17 of the LVNE-Tr (Vth low) region. In this manner, like the above-described first embodiment, the semiconductor device including the low-voltage N-channel transistor LVNE-Tr of the double-well structure can easily be formed. As a result, even in the case where a negative voltage is applied to the gate of the selected cell and the word line is set at a negative potential, the flow of a forward current can be prevented when the P-type semiconductor substrate 10 is set a negative potential. Thus, the electric current consumption can be reduced. As a result, the semiconductor device with good quality can be obtained.

In addition, the LVNE-Tr (Vth low) region and LVNE-Tr (Vth high) region, in which transistors with different thresholds are formed, can easily be selectively formed.

In the above-described second embodiment, the LVNE-Tr (Vth low) region and LVNE-Tr (Vth high) region are formed. However, the LVNE-Tr (Vth low) region may not be formed.

### Third Embodiment

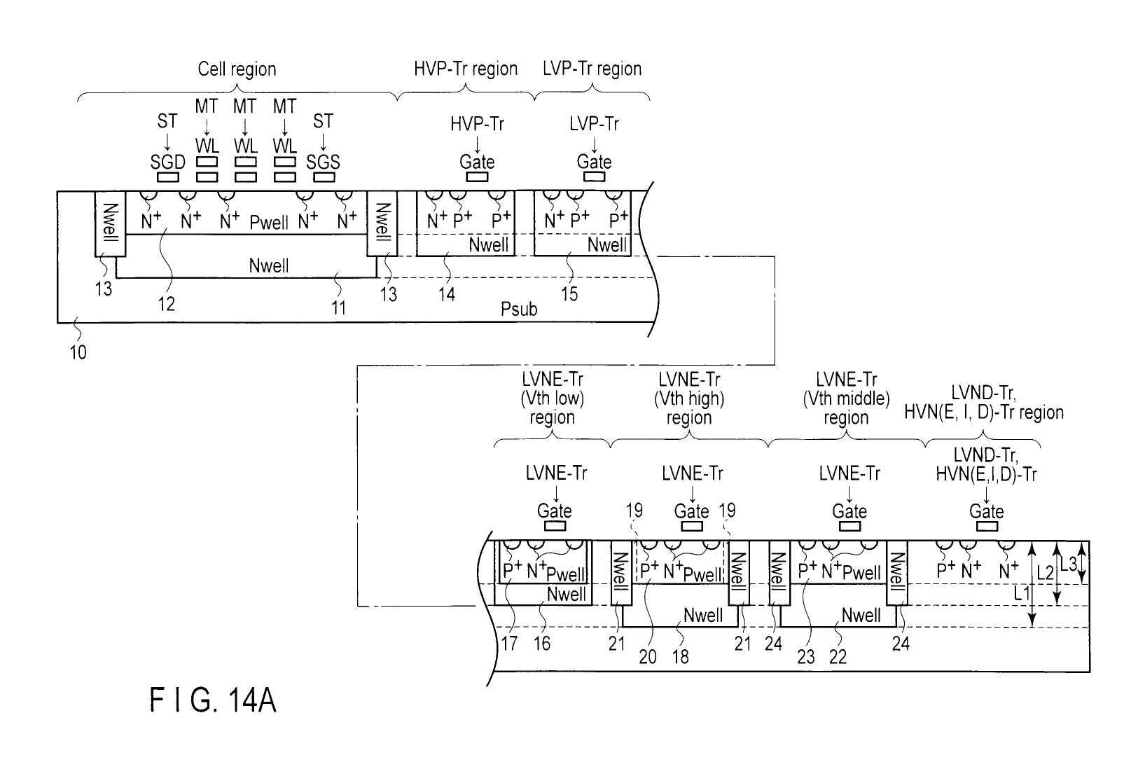

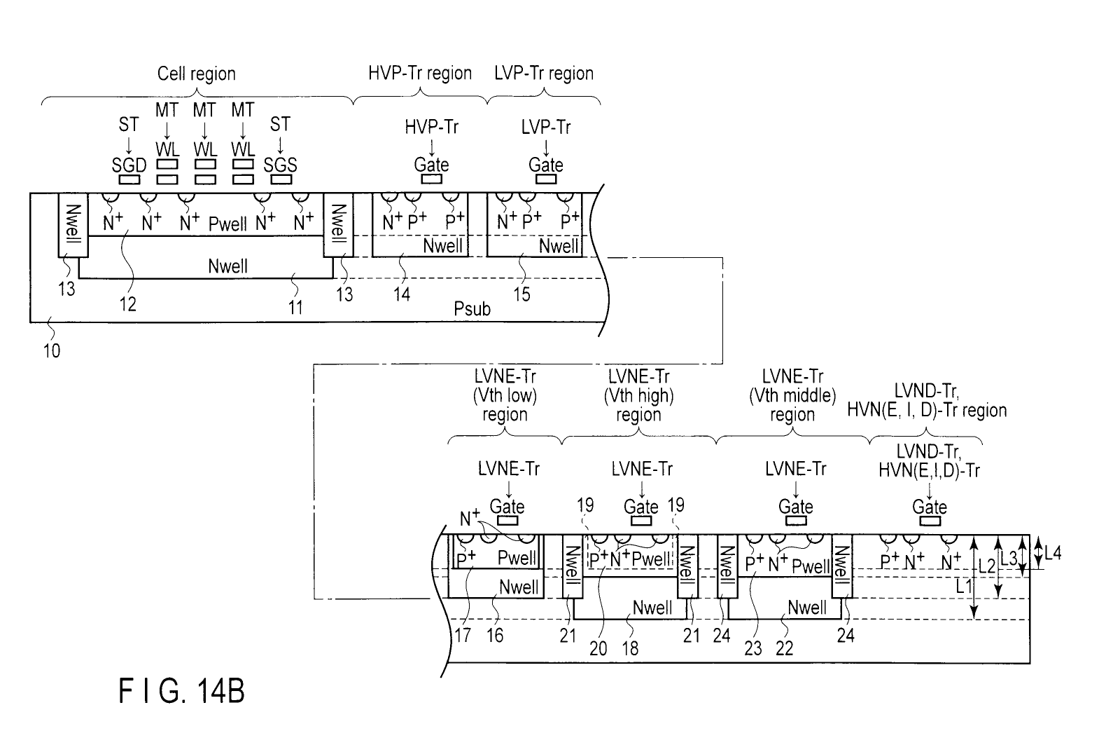

Next, referring to FIG. 14A, the basic structure of a semiconductor device according to a third embodiment is described. FIG. 14A is a cross-sectional view showing the basic structure of the semiconductor device according to the third embodiment. The basic structure and the basic manufacturing method of this embodiment are the same as those of the above-described first and second embodiments. Thus, a description of parts, which can be easily guessed from the above-described matters and examples, is omitted.

As shown in FIG. 14A, the semiconductor device according to the third embodiment further includes a LVNE-Tr (Vth middle) region, in addition to the respective regions of the semiconductor device according to the second embodiment. Specifically, the semiconductor device of the present embodiment includes a Cell region, an HVP-Tr region, an LVP-Tr region, an LVNE-Tr (Vth low) region, an LVNE-Tr (Vth high) region, an LVNE-Tr (Vth middle) region, and an LVND-Tr, HVN(E, I, D)-Tr region.

For example, in a P-type semiconductor substrate (Psub) 10, N wells 11, 13, 14, 15, 16, 18, 21, 22 and 24 and P wells 12, 17, 19, 20 and 23 are formed.

In the LVNE-Tr (Vth middle) region, a low-voltage N-channel MOS transistor LVNE-Tr, which constitutes, for example, a part of the data memory circuit 9, is formed. Specifically, the P well 23, which has a depth L3 (L1>L3) from the surface of the semiconductor substrate 10 to the bottom surface of the P well 23, is formed on the N well 22 which has a depth L1 from the surface of the semiconductor substrate 10 to the bottom of the N well 22. In addition, the N well 24 having a depth L2 (L1>L2>L3) from the surface of the semiconductor substrate 10 to the bottom surface of the N well 24 is formed near a boundary at side surfaces of the N well 22 and P well 23. Further, a low-voltage N-channel MOS transistor LVNE-Tr is formed on the semiconductor substrate 10 and on the P well 23. In the P well 23, N-type diffusion layers (N⁺ layers) are formed as a source/drain of the low-voltage N-channel MOS transistor LVNE-Tr. A control gate (Gate) is formed via a gate insulation film (not shown) on a channel region between the N⁺ layers and on the P well 23. The impurity concentration of the P well 23 is higher than the impurity concentration of the P well 17 and is lower than the impurity concentration of the P well 20. In addition, the channel concentration of the low-voltage N-channel MOS transistor LVNE-Tr in the LVNE-Tr (Vth low) region, the channel concentration of the low-voltage N-channel MOS transistor LVNE-Tr in the LVNE-Tr (Vth middle) region and the channel concentration of the low-voltage N-channel MOS transistor LVNE-Tr in the LVNE-Tr (Vth high) region are equal. As a result, the threshold voltages of the respective transistors are different.

As shown in FIG. 14B, in the LVNE-Tr (Vth high) region, the depth from the surface of the semiconductor substrate 10 to the bottom surface of the P well 19 is L3. On the other hand, in the LVNE-Tr (Vth high) region, the depth from the surface of the semiconductor substrate 10 to the bottom surface of the P well 20 is L4 which is less than L3. Specifically, the P well 20 is surrounded by the P well 19, and the P well 20 is not in contact with the N well 18 or 21. As a result, the gradient of the impurity concentrations of the N well 18 and P well 20 can be decreased. As a result, a leak current between the N well 18 and P well 20 can be decreased.

In the meantime, in the LVNE-Tr (Vth low) region, the depth of the P well 17 from the surface of the semiconductor substrate 10 to the bottom surface of the P well 17 is also substantially equal to L4. In the LVNE-Tr (Vth middle) region, the depth of the P well 23 from the surface of the semiconductor substrate 10 to the bottom surface of the P well 23 is also substantially equal to L3.

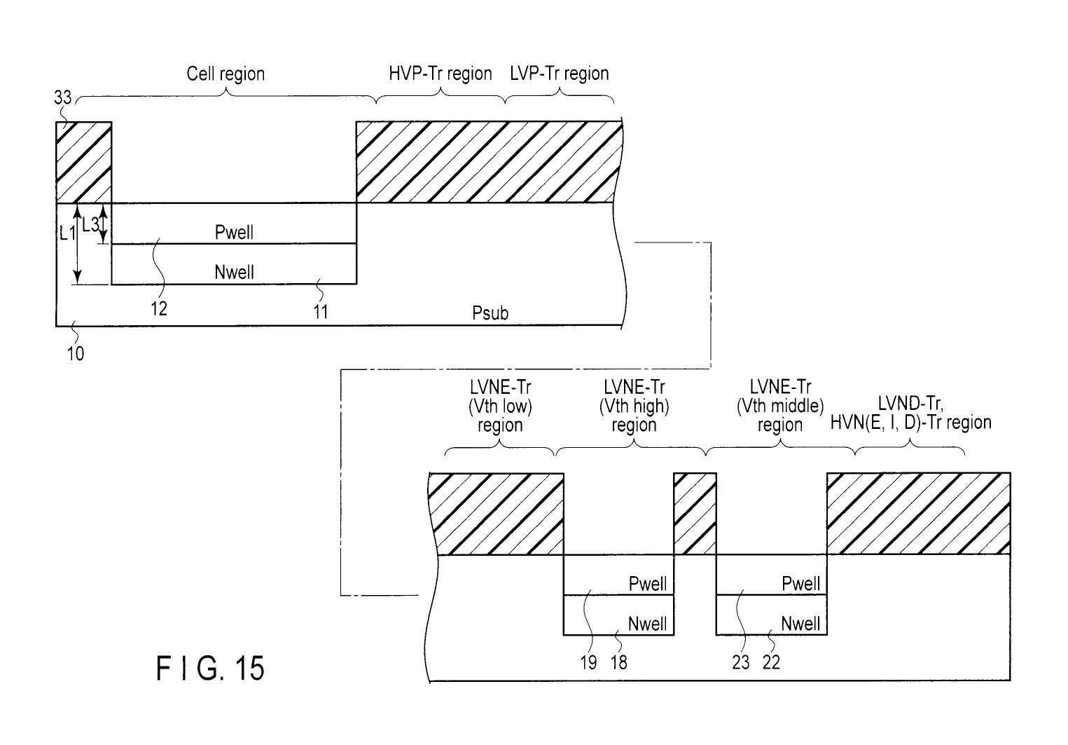

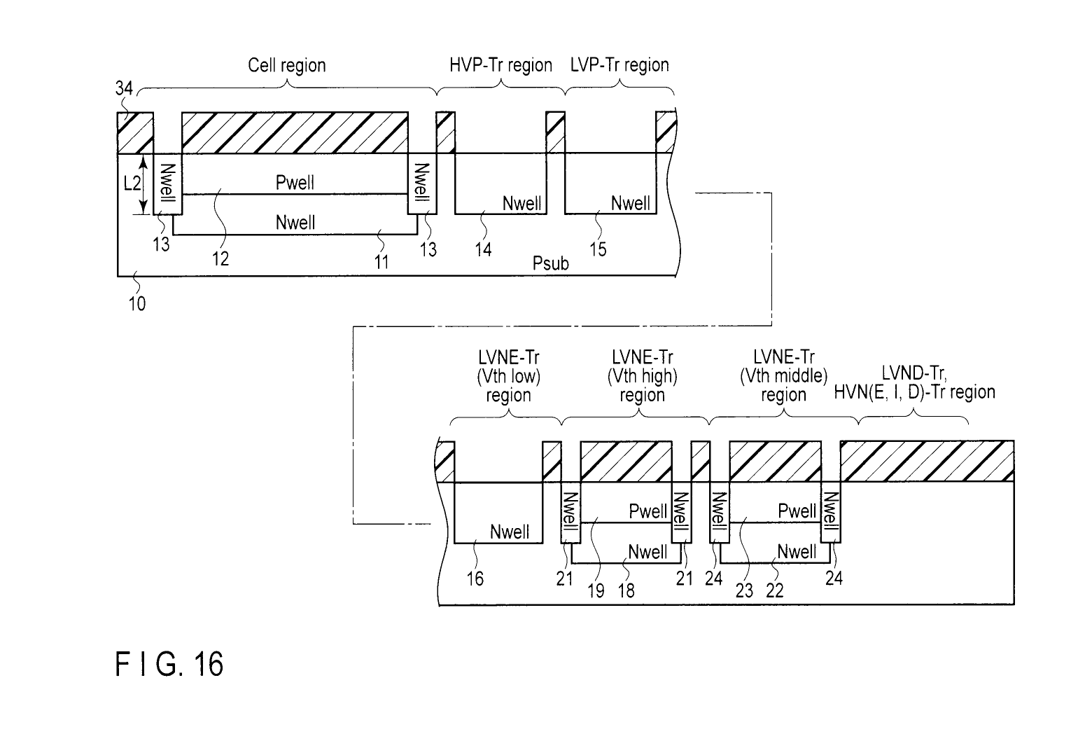

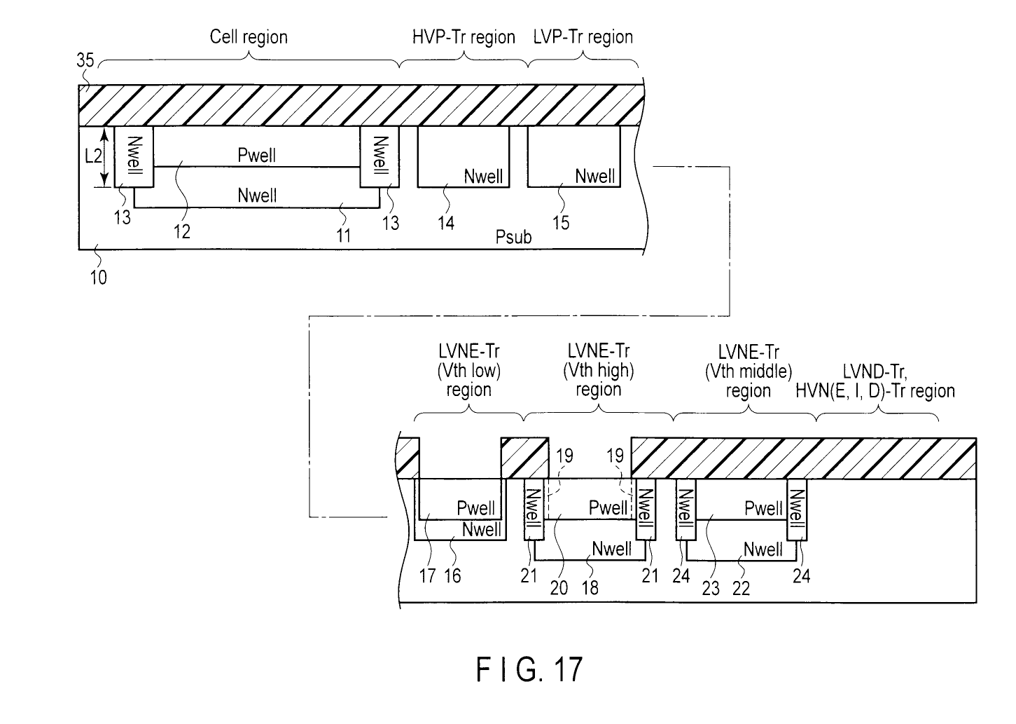

The method of forming the LVNE-Tr (Vth middle) region, up to the fabrication of the structure shown in FIG. 15 and FIG. 16, is the same as the method of forming the LVNE-Tr (Vth high) region, which has been described with reference to FIG. 9 and FIG. 10A in connection with the second embodiment. As shown in FIG. 17, the LVNE-Tr (Vth middle) region is covered with a resist at the time of doping, as illustrated in FIG. 11, P-type impurities in the LVNE-Tr (Vth high) region. Then, using a well-known manufacturing method, memory cell transistors MT, select transistors ST and N⁺ layers are formed in the P well 12 of the Cell region. A high-voltage P-channel MOS transistor HVP-Tr, P⁺ layers and an N⁺ layer are formed in the N well 14 of the HVP-Tr region. A low-voltage P-channel MOS transistor LVP-Tr, P⁺ layers and an N⁺ layer are formed in the N well 15 of the LVP-Tr region. A low-voltage N-channel MOS transistor LVNE-Tr, N⁺ layers and a P⁺ layer are formed in the P well 17 of the LVNE-Tr (Vth low) region. A low-voltage N-channel MOS transistor LVNE-Tr, N⁺ layers and a P⁺ layer are formed in the P well 20 of the LVNE-Tr (Vth high) region. A low-voltage N-channel MOS transistor LVNE-Tr, N⁺ layers and a P⁺ layer are formed in the P well 23 of the LVNE-Tr (Vth middle) region. A low-voltage N-channel MOS transistor LVND-Tr or a high-voltage N-channel MOS transistor HVN(E, I, D)-Tr is formed in the LVND-Tr, HVN(E, I, D)-Tr region of the semiconductor substrate 10. In addition, element isolation regions are formed between the respective regions.

According to the above-described embodiment, the N well 22 of the LVNE-Tr (Vth middle) region is formed at the same time as the N well 11 of the Cell region and the N well 18 of the LVNE-Tr (Vth high) region. The P well 23 is formed at the same time as the P well 12 of the Cell region and the P well 19 of the LVNE-Tr (Vth high) region. The N well 24 is formed at the same time as the N well 13 of the Cell region, the N well 14 of the HVP-Tr region, the N well 15 of the LVP-Tr region, the N well 16 of the LVNE-Tr (Vth low) region and the N well 21 of the LVNE-Tr (Vth high) region. In this manner, like the above-described first embodiment, the semiconductor device including the low-voltage N-channel transistor LVNE-Tr of the double-well structure can easily be formed. As a result, even in the case where a negative voltage is applied to the gate of the selected cell and the word line is set at a negative potential, the flow of a forward current can be prevented when the P-type semiconductor substrate 10 is set a negative potential. Thus, the semiconductor substrate can quickly be charged to a negative potential, and the electric current consumption can be reduced. As a result, the semiconductor device with good quality can be obtained.

In addition, the LVNE-Tr (Vth low) region, the LVNE-Tr (Vth middle) region and LVNE-Tr (Vth high) region, in which transistors with different thresholds are formed, can easily be selectively formed.

In the above-described second embodiment, the LVNE-Tr (Vth low) region, LVNE-Tr (Vth middle) region and LVNE-Tr (Vth high) region are formed. However, the LVNE-Tr (Vth low) region and the LVNE-Tr (Vth high) region may not be formed.

In each of the above-described embodiments, the N well 15 of the LVP-Tr region and the N well 16 of the LVNE-Tr region are isolated. However, the LVP-Tr region and the LVNE-Tr region may be configured to share a common N well.

Besides, it is effective to use a method of doping boron in the channel region of the low-voltage N-channel transistor LVNE-Tr, as the method of adjusting the threshold of the low-voltage N-channel transistor LVNE-Tr of the LVNE-Tr region.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate of a first conductivity type;
a first region including a first well of a second conductivity type which is formed in the semiconductor substrate, a second well of the first conductivity type which is formed in the semiconductor substrate and on the first well, and a memory cell transistor which is formed on the second well;
a second region including a third well of the second conductivity type which is formed in the semiconductor substrate, and a first transistor of the first conductivity type which is formed on the third well;
a third region including a second transistor of the second conductivity type which is formed on the semiconductor substrate; and
a fourth region including a fourth well of the second conductivity type which is formed in the semiconductor substrate, a fifth well of the first conductivity type which is formed in the semiconductor substrate and on the fourth well, and a third transistor of the second conductivity type which is formed on the fifth well,
wherein a position of each of bottom surfaces of the first well and the fourth well is lower than a position of a bottom surface of the third well, and the position of the bottom surface of the third well is lower than a position of each of bottom surfaces of the second well and the fifth well.

2. The device of claim 1, further comprising a fifth region including a sixth well of the second conductivity type which is formed in the semiconductor substrate, a seventh well of the first conductivity type which is formed in the semiconductor substrate and on the sixth well, an eighth well of the first conductivity type which is formed in the seventh well, and a fourth transistor of the second conductivity type which is formed on the eighth well,
wherein a position of a bottom surface of the sixth well is equal in height to the position of each of the bottom surfaces of the first well and the fourth well, and a position of a bottom surface of the seventh well is equal in height to the position of each of the bottom surfaces of the second well and the fifth well.

3. The device of claim 2, wherein the position of the bottom surface of the seventh well is equal to a position of a bottom surface of the eighth well.

4. The device of claim 2, wherein a position of a bottom surface of the eighth well is higher than the position of the bottom surface of the seventh well.

5. The device of claim 2, further comprising a ninth well of the second conductivity type which is formed in the semiconductor substrate and near side surfaces of the sixth well and the seventh well, a position of a bottom surface of the ninth well being equal in height to the position of the bottom surface of the third well.

6. The device of claim 2, wherein an impurity concentration of the fifth well is lower than an impurity concentration of the eighth well.

7. The device of claim 2, wherein an impurity concentration of the eighth well is higher than an impurity concentration of the seventh well.

8. The device of claim 2, further comprising a sixth region including a tenth well of the second conductivity type which is formed in the semiconductor substrate, an eleventh well of the first conductivity type which is formed on the tenth well, and a fifth transistor of the second conductivity type which is formed on the eleventh well,
wherein a position of a bottom surface of the tenth well is equal in height to the position of the bottom surface of the third well, and a position of a bottom surface of the eleventh well is equal in height to a position of a bottom surface of the eighth well.

9. The device of claim 8, wherein the position of the bottom surface of the second well is higher than the position of the bottom surface of the eleventh well.

10. The device of claim 8, wherein the position of the bottom surface of the second well is lower than the position of the bottom surface of the eleventh well.

11. The device of claim 8, wherein an impurity concentration of the fifth well is higher than an impurity concentration of the eleventh well.

12. The device of claim 1, further comprising a twelfth well of the second conductivity type which is formed in the semiconductor substrate and near side surfaces of the fourth well and the fifth well, a position of a bottom surface of the twelfth well being equal in height to the position of the bottom surface of the third well.

13. The device of claim 1, further comprising a thirteenth well of the second conductivity type which is formed in the semiconductor substrate and near side surfaces of the first well and the second well, a position of a bottom surface of the thirteenth well being equal in height to the position of the bottom surface of the third well.

14. The device of claim 1, wherein the first conductivity type is a p type, and the second conductivity type is an n type.

15. A method of manufacturing a semiconductor device including at least a first region, a second region, a third region and a fourth region, the method comprising:
forming a first mask on a semiconductor substrate of a first conductivity type in the second region and the third region;
forming a first well of a second conductivity type in the first region and a second well of the second conductivity type in the fourth region by using the first mask;
forming a third well of the first conductivity type, which is shallower than the first well, in the first region, and a fourth well of the first conductivity type, which is shallower than the second well, in the fourth region, by using the first mask;
forming a second mask on the semiconductor substrate in the first region, the third region and the fourth region; and
forming a fifth well of the second conductivity type, which is shallower than the first well and is deeper than the third well, in the second region, by using the second mask.

16. The method of claim 15, wherein said forming the fifth well by using the second mask includes forming a sixth well of the second conductivity type near side surfaces of the first well and the third well.

17. The method of claim 15, wherein said forming the fifth well by using the second mask includes forming a seventh well of the second conductivity type near side surfaces of the second well and the fourth well.

18. The method of claim 15, wherein said forming the first well and the second well by using the first mask includes forming an eighth well of the second conductivity type in a fifth region,
said forming the third well and the fourth well by using the first mask includes forming a ninth well of the first conductivity type, which is shallower than the eighth well, in the fifth region, and
the method further comprises:
forming a third mask on the semiconductor substrate in the first region, the second region, the third region and the fourth region; and
forming a tenth well of the first conductivity type in the ninth well, which has a higher impurity concentration than the ninth well, in the fifth region, by using the third mask.

19. The method of claim 18, wherein said forming the fifth well by using the second mask includes forming an eleventh well of the second conductivity type, which is shallower than the first well and is deeper than the third well, in a sixth region, and
said forming the tenth well by using the third mask includes forming a twelfth well of the first conductivity type, which is shallower than the eleventh well, in the sixth region.

20. The method of claim 18, wherein said forming the fifth well by using the second mask includes forming a thirteenth well of the second conductivity type near side surfaces of the eighth well and the ninth well.
